(19) United States
(12) Patent Application Publication
(10) Pub. No.: US 2007/0076514 A1
(43) Pub. Date: Apr. 5, 2007

(54) Lus semiconductor and application circuit

(76) Inventor: Chao-Cheng Lu, Taipei (TW)

Correspondence Address: LU, CHAO-CHENG, 4-4, Alley 27, Lane 143, Chun Kung Road, Taipei, 11614, TW

(21) Appl. No.: 11/246,839

(22) Filed: Oct. 3, 2005

(51) Int. Cl. G11C 8/00

(52) U.S. Cl. 365/230.06

(57) ABSTRACT

The Lus Semiconductor in this invention is characterized by replacing the static shielding diode (SSD) of traditional Power Metal Oxide Semiconductor Field Effect Transistors (Power MOSFETs) with polarity reversed (comparing with traditional SSD) SSD, Schottky Diode, or Zener Diode, or face-to-face or back-to-back coupled Schottky Diodes, Zener Diodes, Fast Diodes, or Four Layer Devices such as DIAC and Triac. With the proposed Power MOSFETs of which the drain to source resistors (Rds) are quite low, two major functions of high efficiency AC/DC conversion and DC voltage regulation may be achieved.

### BACKGROUND OF THE INVENTION

1. Field of the Invention

This invention is related to Power Metal Oxide Semiconductor Field Effect Transistors, Power MOSFETs, especially Power MOSFETs with novel structures replacing conventional Static Shielding Diodes, SSDs. According to this invention, traditional SSDs in Power MOSFETs may be replaced with polarity reversed (comparing with traditional SSD) SSDs, Schottky Diodes, or Zener Diodes, or face-to-face/back-to-back coupled Schottky Diodes, Zener Diodes, Fast Diodes, or Four Layer Devices such as DIAC and Triac such that conventional functions are preserved and need only to consider the amplitude of the reverse biased voltage for proper semiconductor operating voltage. As shown in FIG. 2 (E) or (F), the amplitude of the reverse biased operating voltage, i.e. Zener Voltage, may be configured according to the needs in this invention and would be higher than the DC output voltage in actual applications. That is, the voltage of conventional SSD in Power MOSFETs is higher than the AC voltage at input side, and the Zener voltage of the polarity reversed coupled Zener Diode is higher than the DC output voltage. According to such design philosophy of this invention, functions of half-wave rectification and voltage regulation may be achieved with a single Power MOSFET in coordination with auxiliary circuits, and functions of full-wave rectification and voltage regulation may be achieved with two pieces of Power MOSFETs in coordination with auxiliary circuits. Hence, functions of high efficiency rectification and voltage regulation may be achieved.

2. Description of the Related Art

In order to get stable output voltage in conventional switching power supplies, it is necessary to implement circuits with rectifier diodes and feedback circuits of PWM systems. FIG. 3 (A) shows the structure of a conventional N-channel power MOSFET and FIG. 3 (B) shows the structure of a conventional P-channel power MOSFET, both with static shielding diodes, SSD. FIG. 4 shows a power regulation circuit utilizing UC3842, in which VD6 and VD7 are responsible for rectification and IC2 TL431, photo coupler 4N35 and PWM IC MC3842 are responsible for voltage regulation. Such scheme comes with the following drawbacks:

1. While the current through diode VD6 is set to be IF=1.5 A and the voltage drop of the forward biased voltage of a diode VD2 is approximately VF≈0.7V, then the power consumption is about 0.7V*1.5 A=1.05 W. If the output is 20 A, the power consumption becomes 0.7V*20 A=14 W, which is too much power consumption to utilize in actual practice.

2. While supplying multiple DC output of different amplitude of voltage in a PWM system, some DC output may not be regulated by such system. For example, the primary output 12V, 1.5 A in FIG. 4 is regulated while the secondary output 5V, 0.2 A is not regulated.

3. Noise is an inevitable problem in PWM power regulation systems.

### SUMMARY OF THE INVENTION

In order to provide semiconductor devices which may elevate the efficiency of rectification and provide function of voltage regulation, this invention is proposed according to the following objects.

The first object of this invention is to provide semiconductor devices that eliminate the drawback of high power consumption of conventional power rectifiers utilizing diodes, such as Schottky diodes.

The second object of this invention is to provide semiconductor devices that require no feedback circuits applying to the front end circuit for stable output.

The third object of this invention is to eliminate the drawback that only certain groups of output voltage are able to be regulated while other plurality of output may not be able to be regulated in the conventional PWM switching power circuits.

In order to solve the problem of high power consumption in conventional rectification and voltage regulation systems, the present invention possess the following characteristics:

1. Unlike the manufacture process of conventional power MOSFETs, the polarity of single parasitic diode, SSD, is reversed or replaced the SSD with two pieces of face-to-face/back-to-back coupled diodes, i.e., in the manufacture process of power MOSFETs, coupling characteristic structures of Lus Semiconductor between drain node and source node as shown in FIG. 2.

2. The characteristic structures of Lus Semiconductor may be externally coupled between drain node and source node as shown in FIG. 2 if no parasitic diodes exist in conventional power MOSFETs.

3. Lus Semiconductors in the present invention may also be applied in conventional PWM power supply systems. For example, in FIG. 4, VD6 may be replaced with Lus Semiconductors for rectification purpose only, and VD7 may also be replaced with Lus Semiconductors such that the efficiency of rectification may be improved.

According to the defects of the conventional technology discussed above, a novel solution, the Lus Semiconductor, is proposed in the present invention, which provides power MOSFETs with the two functions of rectification and voltage regulation.

### BRIEF DESCRIPTION OF THE DRAWINGS

FIG. 1 shows the structures of an N-Channel Power MOSFET and a P-Channel Power MOSFET of the Lus Semiconductor according to the present invention.

FIG. 2 shows characteristic circuit structures of the Lus Semiconductor coupled between the drain and source of the power MOSFETs shown in FIG. 1.

FIG. 3 shows the structures of a conventional N-Channel MOSFET and a conventional P-Channel MOSFET.

FIG. 4 shows a power regulation circuit utilizing UC3842.

FIG. 5 shows an application circuit utilizing one embodiment of the Lus Semiconductor according to the present invention.

FIG. 6 shows another application circuit utilizing one embodiment of the Lus Semiconductor according to the present invention.

### DETAILED DESCRIPTION OF THE INVENTION

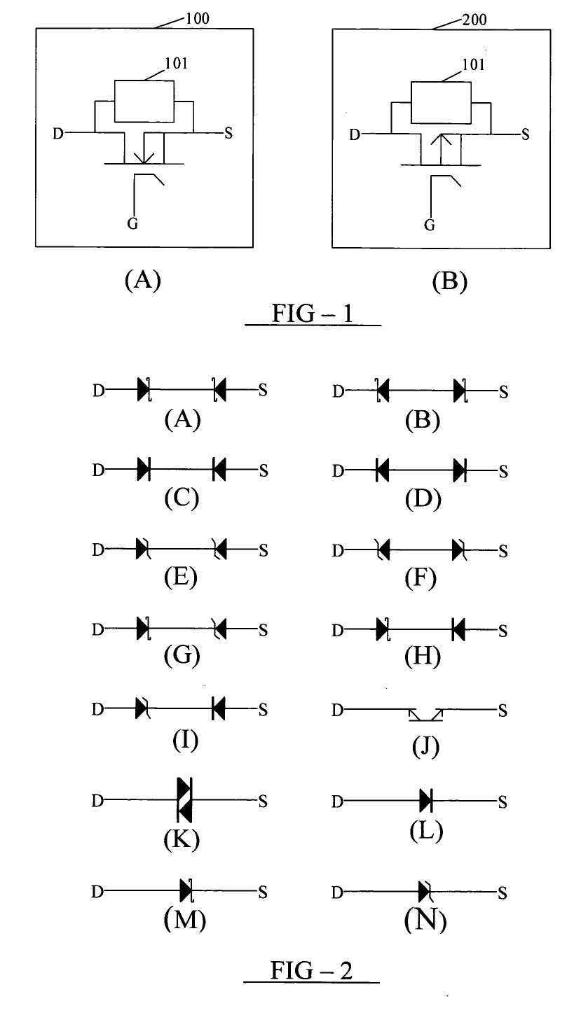

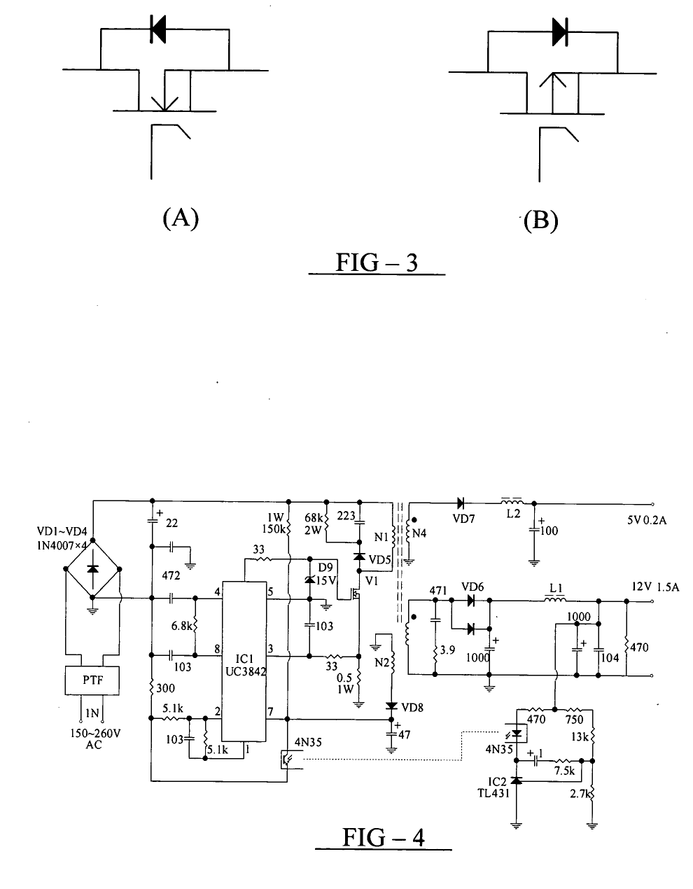

FIG. 1 shows the structures of an N-Channel power MOSFET (100) and a P-Channel power MOSFET (200) of Lus Semiconductor according to the present invention. FIG. 2 shows several characteristic circuit structures (101) of Lus Semiconductor that may be coupled between the drain node and the source node of power MOSFETs shown in FIG. 1. A pair of face-to-face coupled Schottky diodes and a pair of back-to-back coupled Schottky diodes are shown in FIG. 2 (A) and FIG. 2 (B) respectively, and each of the two may be then coupled to the drain node and the source node of the power MOSFETs. A pair of face-to-face coupled SSDs and a pair of back-to-back coupled SSDs are shown in FIG. 2 (C) and FIG. 2 (D) respectively, and each of the two may be then coupled to the drain node and source node of the power MOSFETs. A pair of face-to-face coupled Zener diodes and a pair of back-to-back coupled Zener diodes are shown in FIG. 2 (E) and FIG. 2 (F) respectively, and each of the two may be then coupled to the drain node and source node of the power MOSFETs. FIG. 2 (G) shows a pair of face-to-face coupled Schottky diode and Zener diode, which may then be coupled to the drain node and the source node of the power MOSFETs. FIG. 2 (H) shows a pair of face-to-face coupled Schottky diode and SSD which may then be coupled to the drain node and the source node of the power MOSFETs. FIG. 2 (I) shows a pair of face-to-face coupled Zener diode and fast diode which may then be coupled to the drain node and the source node of the power MOSFETs. FIG. 2 (J) shows a DIAC four layer semiconductor and FIG. 2 K shows a Triac four layer semiconductor, each of the two may then be coupled to the drain node and the source node of the power MOSFETs. The characteristic circuit structures (101) shown in FIG. 2 (A)˜(K) may all be coupled to the drain node and the source node of the power MOSFETs and Lus Semiconductors (100)(200) are thus constructed. With the characteristic circuit structures (101) shown in FIGS. 2 (A)˜(K), high efficiency rectification and voltage regulation may be achieved, with a single power MOSFET. Comparing with the structures of a conventional N-Channel MOSFET or a conventional P-Channel MOSFET shown in FIG. 3, one can tell that thy are the totally different from the characteristic circuit structures of Lus Semiconductors.

In order to meet the needs of conventional PWM power supplies, as shown in FIG. 2(L), FIG. 2(M) and FIG. 2(N), the polarities of the parasitic diodes of conventional N-Channel or P-Channel MOSFETs may be reversed, thus become the characteristic circuit structures (101) of Lus Semiconductors which may replace rectifiers in conventional circuits, for example, VD6 and VD7 in FIG. 4, and still preserve the characteristic functions of those of conventional SSDs.

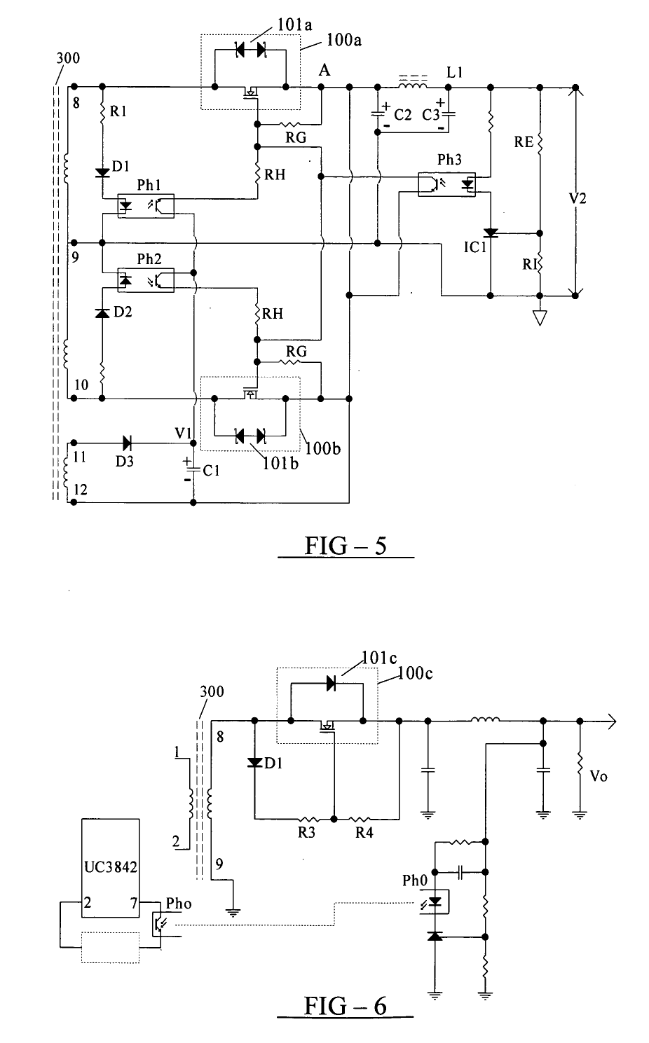

FIG. 5 shows an application circuit utilizing one embodiment of the Lus Semiconductor according to the present invention. As shown in this figure, all N-Channel power MOSFETs are replaced with N-Channel Lus Semiconductors (100a, 100b). In operation, while a high frequency AC voltage at the node 8 of the first secondary winding of the high frequency transformer 300 is at positive half cycle, the positive voltage passes through the current-limiting resistor R1, diode D1 and the LED of the photo coupler Ph1 and reaches the middle node 9. Meanwhile the high frequency voltage across node 11 and node 12 of the second secondary winding of the high frequency transformer 300 is half-wave rectified by the high frequency diode D3 such that a DC voltage V1 is obtained across the filter capacitor C1. The positive voltage V1 reaches a voltage-dividing resistor RH through the output side of the photo coupler Ph1, and conducts the drain and source of the Lus Semiconductors (100a, 100b). The positive half cycle AC voltage at node 8 passes through the drain and source of the Lus Semiconductor (100a) and a π-type filter constructed with a filter capacitor C2, an inductor L1 and a filter capacitor C3, thus becomes DC output voltage V2. While the AC voltage at the node 10 of the first secondary winding of the high frequency transformer 300 is at positive half cycle, the operation is identical to that while the AC voltage at the node 8 of the first secondary winding of the high frequency transformer 300 is at positive half cycle. Because those two half-cycle circuits are commonly connected at node A, full-wave rectification may be achieved.

While the output voltage V2 is higher than a pre-defined voltage, an adjustable precision shunt regulator integrated circuit IC1 may be activated and meanwhile the collector and the emitter at the output side of a photo coupler Ph3 may be conducted that makes the gate and the source of the Lus Semiconductors (100a, 100b) short-circuited and stops rectifying, thus voltage V2 may drop. While the voltage V2 is low enough that deactivates IC1, the Lus Semiconductors (100a, 100b) may then start rectifying and make voltage V2 rise. According to the operation, the Lus Semiconductors (100a, 100b) are capable of rectification and voltage regulation. While the voltage at node 8 of the high frequency transformer 300 is set to be positive, the reverse biased break down voltage of the Schotty diode of the characteristic circuit structure (101a) of the Lus Semiconductor (100a) is higher than the positive voltage at node 8, thus the voltage at node 8 may not pass through the reversed Shottky diode but through the drain and source of the Luz Semiconductor (100a). While the output voltage V2 is present, even though the voltage at node 8 is at the negative half cycle of the AC voltage, because the reverse biased break down voltage of the reverse coupled Schotty diode in the characteristic circuit structure (101a) is higher than the output voltage V2, the possibility that the first secondary winding may be burned out by the reverse current of conventional power MOSFETs can be eliminated. The operation of the characteristic circuit structure (101b) in the Lus Semiconductor (100b) at node 10 is identical. According to the operation of the characteristic circuit structure (101) in the present invention, the reverse biased break down voltage may be configured according to applications and shall not be limited.

FIG. 6 shows another application circuit utilizing another embodiment of the Lus Semiconductor (100) according to the present invention. Actually it is the circuit identical to that shown in FIG. 4 except for the power MOSFET is replaced by a Lus Semiconductor (100c). In FIG. 6, while the voltage at node 8 of the first secondary winding of the high frequency transformer 300 is positive, it passes through the diode D1 and the voltage-dividing resistor R3 and supplies positive voltage to the gate of the Lus Semiconductor (100c) such that the drain node and the source node are conducted. Thus, the π-type filter thereafter gets a positive voltage. Because the resistor RDS measured between the drain and the source of the power MOSFET is small, most current may flow through the drain node and the source node instead of through the diode in the characteristic circuit structure (101c). While the AC voltage at node 8 is at negative half cycle, the DC voltage of the π-type filter may not flow back to the node 8 of the first secondary windings of the high frequency transformer 300, therefore protects node 8 of the first secondary windings from being burned out by the reverse current source. On the contrary, in FIG. 4, because the polarity of the SSD of the conventional power MOSFETs is reverse coupled comparing with the SSD of the present invention, node 8 of the first secondary winding may possibly be burned out by the reverse DC current. This also shows some concrete evidence of the benefit of the present invention. The operations of PWM voltage regulation in UC3842 are known to the people skilled in the art and will not be discussed here. One thing to be emphasized is that the Lus Semiconductor (100) shown in FIG. 6 may also be implemented with the auxiliary circuit shown in FIG. 5, and shall not be limited.

What is claimed is:

1. A power semiconductor device in which a characteristic circuit being developed between a drain node and a source node of a metal oxide semiconductor field effect transistor (MOSFET) during manufacture process such that said power semiconductor device possessing functions of power rectification and voltage regulation.

2. The power semiconductor device according to claim 1 in which said characteristic circuit is chosen from the group consisting of a pair of back-to-back or face-to-face series coupling Schotty diodes, a pair of back-to-back or face-to-face series coupling SSDs, a pair of back-to-back or face-to-face series coupling Zener diodes, a pair of back-to-back or face-to-face series coupling Schotty diode and Zener diode, a pair of back-to-back or face-to-face series coupling Schotty diode and SSD, and a pair of back-to-back or face-to-face series coupling Zener diode and SSD, wherein said back-to-back coupling means P-type nodes interconnecting and said face-to-face coupling means N-type nodes interconnecting.

3. The power semiconductor device according to claim 1, wherein said characteristic circuit is a piece of four layer semiconductor device.

4. The power semiconductor device according to claim 3, wherein said four layer semiconductor device is a piece of DIAC or Triac.

5. The power semiconductor device according to claim 1, wherein said characteristic circuit comprising a P-type node and an N-type node that coupling respectively to said drain node and said source node of said MOSFET.

6. The power semiconductor device according to claim 5 wherein said characteristic circuit is one fast diode, one Schotty diode or one Zener diode.

7. A power semiconductor device in which a characteristic circuit is coupling externally between a drain node and a source node of a metal oxide semiconductor field effect transistor (MOSFET), such that said device possessing functions of rectification and voltage regulation.

8. The power semiconductor device according to claim 7 in which said characteristic circuit is chosen from the group consisting of a pair of back-to-back or face-to-face series coupling Schotty diodes, a pair of back-to-back or face-to-face series coupling SSDs, a pair of back-to-back or face-to-face series coupling Zener diodes, a pair of back-to-back or face-to-face series coupling Schotty diode and Zener diode, a pair of back-to-back or face-to-face series coupling Schotty diode and SSD, and a pair of back-to-back or face-to-face series coupling Zener diode and SSD, wherein said back-to-back coupling means P-type nodes interconnecting and said face-to-face coupling means N-type nodes interconnecting.

9. The power semiconductor device according to claim 7, wherein said characteristic circuit is a piece of four layer semiconductor device.

10. The power semiconductor device according to claim 9, wherein said four layer semiconductor device is a piece of DIAC or Triac.

11. The power semiconductor device according to claim 7, wherein said characteristic circuit comprising a P-type node and an N-type node that coupling respectively to said drain node and said source node of said MOSFET.

12. The power semiconductor device according to claim 11, wherein said characteristic circuit is one fast diode, one Schotty diode or one Zener diode.

13. A rectifier circuit comprising:
at least one power semiconductor device as in any preceding claims; and
an auxiliary circuit coupling to said power semiconductor device, such that a voltage source is half-wave or full-wave rectified and regulated by said rectifier circuit providing a DC output voltage.

14. The rectifier circuit according to claim 13, wherein said auxiliary circuit providing an auxiliary voltage to said power semiconductor device such that said power semiconductor device is biased in operating region.

15. The rectifier circuit according to claim 14, further comprising:
a high frequency transformer comprising a first secondary winding and a second secondary winding, wherein:
while a positive half cycle of AC voltage feeding to a first node of said first secondary winding, said positive half cycle of AC voltage passing though said auxiliary circuit, reaching a second node of said first secondary winding and applying to said power semiconductor device; and
a voltage across said second secondary winding providing said auxiliary voltage through said auxiliary circuit and conducting/isolating a drain node and a source node of said power semiconductor device.

16. The rectifier circuit according to claim 13 wherein said auxiliary circuit comprising a filter circuit coupling to a output node of said power semiconductor such that said rectifier circuit delivering said DC output voltage.

17. The rectifier circuit according to claim 16 wherein said filter circuit is a π-type filter.

18. The rectifier circuit according to claim 13, comprising:
a first and a second power semiconductor device; and
a high frequency transformer comprising a first secondary winding and a second secondary winding; wherein
said auxiliary circuit comprising: a first current limiting resistor, a second current limiting resistor, a first diode, a second diode, a first photo coupler, a second photo coupler, a high frequency diode, a filter capacitor, a first voltage-dividing circuit, a second voltage-dividing circuit and a filter circuit; wherein
while a positive half cycle AC voltage feeding to a first node of said first secondary winding, passing through said first current limiting resistor, said first diode and said first photo coupler, reaching a middle node of said first secondary winding; voltage across two nodes of said second secondary winding being rectified by said high frequency diode, and delivering a positive DC output across said filter capacitor; and said positive DC output reaching said first voltage dividing circuit through a output side of said first photo coupler, conducting a drain node and a source node of said first power semiconductor device; such that said positive half cycle voltage at said first node of said first secondary winding passing through said drain node and said source node of said first power semiconductor device, then delivering said DC output voltage though said filter circuit; and
while a positive half cycle AC voltage feeding to a second node of said first secondary winding, passing through said second current limiting resistor, said second diode and said second photo coupler, reaching a middle node of said first secondary winding; voltage across said second secondary winding being rectified by said high frequency diode, and delivering a positive DC output across said filter capacitor; said positive DC output reaching said second voltage dividing circuit through a output side of said second photo coupler, conducting a drain node and a source node of said second power semiconductor device; such that said positive half cycle AC voltage at said second node of said first secondary winding passing through said drain node and said source node of said second power semiconductor device, then delivering said DC output voltage though said filter circuit.

19. The rectifier circuit according to claim 13, wherein said auxiliary circuit comprising a feedback circuit coupling to said power semiconductor device, and shutting down rectification function of said power semiconductor device while said DC output voltage exceeding a predetermined value until said DC output voltage falling under said predetermined value.

20. The rectifier circuit according to claim 19, wherein said feedback circuit comprising an adjustable precision shunt regulator integrated circuit and a photo coupler; wherein:
while said DC output voltage exceeding said predetermined value, said adjustable precision shunt regulator integrated circuit being activated and the collector node and the emitter node of said photo coupler being conducting, and then the gate node and the source node of said power semiconductor device being conducting, and said power semiconductor device stops rectifying, thus said DC output voltage falls; and
while said DC output voltage falls low enough that said adjustable precision shunt regulator integrated circuit no longer being conducting, said power semiconductor start rectifying, thus said DC output voltage rises.
